(19) United States
(12) Patent Application Publication
(10) Pub. No.: US 2025/0389016 A1
(43) Pub. Date: Dec. 25, 2025

(54) GAS BARRIER FILM MATERIAL, SILICON OXIDE FILM, AND PRODUCTION METHOD OF SILICON OXIDE FILM

(71) Applicant: TOSOH CORPORATION, Shunan-shi, Yamaguchi (JP)

(72) Inventor: Hirokazu CHIBA, Ayase-shi, Kanagawa (JP)

(21) Appl. No.: 18/878,649

(22) PCT Filed: Jul. 13, 2023
(86) PCT No.: PCT/JP2023/025859

§ 371 Date: Dec. 24, 2024

(30) Foreign Application Priority Data
Jul. 14, 2022 (JP) 2022-113127

(51) Int. Cl. C23C 16/40; C23C 16/455

(52) U.S. Cl. CPC C23C 16/401; C23C 16/45523

(57) ABSTRACT

A material for a gas barrier film includes an organosilane compound represented by the following general formula SiR¹_{(4-a-b)}R²ₐR³_{b}. In the formula, R¹ represents a phenyl group, a benzyl group or an alkyl group having 1 to 10 carbon atoms, R² represents an alkenyl group having 2 to 10 carbon atoms or an alkynyl group having 2 to 10 carbon atoms, R³ represents an alkoxy group having 1 to 10 carbon atoms or a hydroxyl group, a is an integer of 1 to 4, and b is an integer of 0 to 3, provided that when R¹, R², or R³ is present in plurality, the plurality thereof may be identical to or different from one another.

### RELATED APPLICATIONS

The present application is a National Phase of International Application No. PCT/JP2023/025859 filed Jul. 13, 2023, which claims priority to Japanese Application No. 2022-113127, filed Jul. 14, 2022.

### TECHNICAL FIELD

The present invention relates to a material for a gas barrier film, to a silicon oxide film, and to a method for producing a silicon oxide film.

### BACKGROUND ART

Some gas barrier films are deposited on a substrate to perform a function of providing gas barrier performance. Examples of such gas barrier films include those deposited by a physical deposition process, a CVD process (Chemical Vapor Deposition process), or the like. Examples of a material of such gas barrier films include oxides, such as SiO₂ and Al₂O₃, and nitrides, such as SiN.

Patent Literature 1, for example, states that a silicon oxide film can be used as a gas barrier film, and that the silicon oxide film is formed by a plasma-enhanced chemical vapor deposition process (PECVD process: Plasma Enhanced Chemical Vapor Deposition process) that uses, as source materials, a specified organosilane compound, such as t-butyltriethoxysilane, and oxygen.

### CITATION LIST

### Patent Literature

Patent Literature 1: International Publication No. 2020/209202

### SUMMARY OF INVENTION

### Technical Problem

In instances where a gas barrier film is formed on a bendable substrate or in instances where a gas barrier film bends under an external force, the gas barrier film may experience bending-induced cracking, formation of voids, and/or delamination from the substrate or another layer and, consequently, may experience a reduction in its gas barrier properties. From the standpoint of avoiding such a reduction, it is desirable that gas barrier films have high flexural resistance. However, silicon oxide films of the related art, such as that of Patent Literature 1, have room for improvement in terms of flexural resistance.

Accordingly, objects of the present invention are to provide a material for a gas barrier film, which is a material for producing a gas barrier film that exhibits sufficient gas barrier properties and has high flexural resistance, to provide a method for producing a silicon oxide film that uses the material for a gas barrier film, and to provide a silicon oxide film.

### Solution to Problem

The present inventor diligently conducted studies to solve the above-described problem and, consequently, discovered that the problem can be solved by a silicon oxide film, a material for a gas barrier film, and a method for producing a silicon oxide film that are described below. Accordingly, the present invention was completed.

Specifically, the present invention has the following aspects.

[1]A silicon oxide film having a film thickness of 300 nm or less and a water vapor transmission rate (WVTR) of 9.0×10⁻³ g/(m²·day) or less, where the water vapor transmission rate is a rate obtained after a U-shape bending test is performed on the silicon oxide film under conditions including a bending radius of 5 mm and bending cycles of 100,000.
[2] The silicon oxide film according to [1], wherein, in an instance where the silicon oxide film is formed on a substrate to form a substrate equipped with a silicon oxide film, a difference (ΔT) is 5% or less, the difference (ΔT) being a result of subtracting a visible light transmittance of the substrate equipped with a silicon oxide film from a visible light transmittance of the substrate itself, and a difference (ΔH) is 5% or less, the difference (ΔH) being a result of subtracting a haze value of the substrate itself from a haze value of the substrate equipped with a silicon oxide film.
[3] The silicon oxide film according to [1] or [2], wherein the silicon oxide film has a modulus of elasticity of 50 GPa or greater and a hardness of 5.0 GPa or greater.
[4]A material for a gas barrier film, the material comprising an organosilane compound represented by general formula (1), shown below:

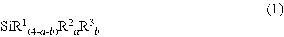

where R¹ represents a phenyl group, a benzyl group or an alkyl group having 1 to 10 carbon atoms, R² represents an alkenyl group having 2 to 10 carbon atoms or an alkynyl group having 2 to 10 carbon atoms,
R³ represents an alkoxy group having 1 to 10 carbon atoms or a hydroxyl group, a is an integer of 1 to 4, and b is an integer of 0 to 3, provided that when R¹, R², or R³ is present in plurality, the plurality thereof may be identical to or different from one another.
   [5] The material for a gas barrier film according to [4], wherein R² is an alkenyl group having 2 to 4 carbon atoms.
   [6] The material for a gas barrier film according to [4], wherein R² is a vinyl group.
   [7] The material for a gas barrier film according to any one of [4] to [6], wherein the organosilane compound is represented by any of general formulae (1A) to (1G), shown below:

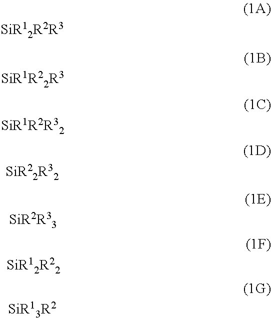

where R¹ represents an alkyl group having 1 to 10 carbon atoms, R² represents an alkenyl group having 2 to 10 carbon atoms, and R³ represents an alkoxy group having 1 to 10 carbon atoms, provided that when R¹, R², or R³ is present in plurality, the plurality thereof may be identical to or different from one another.
   [8] The material for a gas barrier film according to any one of [4] to [7], wherein the organosilane compound is represented by any of general formulae (1A) to (1C), shown below:

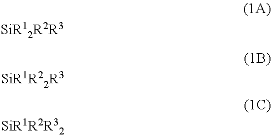

where R¹ represents an alkyl group having 1 to 5 carbon atoms, R² represents an alkenyl group having 2 to 4 carbon atoms, and R³ represents an alkoxy group having 1 to 4 carbon atoms, provided that when R¹, R², or R³ is present in plurality, the plurality thereof may be identical to or different from one another.
   [9]A method for producing a silicon oxide film comprising depositing the material for a gas barrier film according to any one of [4] to [8] on a substrate by using a plasma-enhanced chemical vapor deposition process under conditions including a plasma power of 100 W or greater.
   [10]A silicon oxide film produced by the production method according to [9].

### Advantageous Effects of Invention

With the present invention, it is possible to provide a material for a gas barrier film, which is a material for producing a gas barrier film that exhibits sufficient gas barrier properties and has high flexural resistance, to provide a method for producing a silicon oxide film that uses the material for a gas barrier film, and to provide a silicon oxide film.

### DESCRIPTION OF EMBODIMENTS

Embodiments of the present invention will be described in detail below. In the present specification, when “to” is used to describe a numerical range, the range includes the number preceding “to” as the minimum value and the number following “to” as the maximum value. The minimum value or the maximum value of the numerical range described by using “to” can be combined with any other maximum value or minimum value of any other numerical range described by using “to”. Furthermore, when upper limits and lower limits are separately described, any of the upper limits can be combined with any of the lower limits.

### <Material for Gas Barrier Film>

According to an embodiment, a material for a gas barrier film includes an organosilane compound represented by general formula (1), shown below. The material for a gas barrier film can be deposited by a chemical vapor deposition process, which is preferably a plasma-enhanced chemical vapor deposition process.

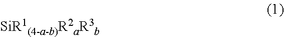

In the formula, R¹ represents a phenyl group, a benzyl group or an alkyl group having 1 to 10 carbon atoms, R² represents an alkenyl group having 2 to 10 carbon atoms or an alkynyl group having 2 to 10 carbon atoms, R³ represents an alkoxy group having 1 to 10 carbon atoms or a hydroxyl group, a is an integer of 1 to 4, and b is an integer of 0 to 3. When R¹, R², or R³ is present in plurality, the plurality thereof may be identical to or different from one another.

With the material for a gas barrier film of the present embodiment, it is possible to produce a gas barrier film (silicon oxide film) having high gas barrier properties (e.g., a water vapor transmission rate (WVTR) of 9.0×10⁻³ g/m²·day or less) and high flexural resistance that are exhibited even when the produced film is thin (e.g., with a film thickness of 300 nm or less). In addition, the silicon oxide film produced with the material for a gas barrier film of the present embodiment exhibits a high visible light transmittance and a low haze value, and, therefore, the absorption of light and scattering of light therein can be avoided. Accordingly, the silicon oxide film can be suitably used in an optical device, such as a light emitting element. Furthermore, the silicon oxide film produced with the material for a gas barrier film of the present embodiment has high hardness and a high modulus of elasticity, and, therefore, a reduction in its gas barrier properties due to the formation of small scratches or voids, delamination from the substrate or another layer, and the like that are caused by an external impact or the like can be prevented.

The “gas barrier performance” means impermeability to gases, such as oxygen, nitrogen, carbon dioxide, and water vapor. The gas barrier performance is evaluated based on the water vapor transmission rate (WVTR) because it is generally employed as a measurement index in the field of the material.

In general formula (1), R¹ may be an alkyl group having 1 to 10 carbon atoms, which is preferable because in this case, high gas barrier properties can be obtained, and a high vapor pressure is suitable for vaporization. R¹ is more preferably an alkyl group having 1 to 5 carbon atoms and even more preferably an alkyl group having 1 to 4 carbon atoms.

The alkyl group having 1 to 10 carbon atoms may have a configuration that is straight, branched, or cyclic. Specific examples of the alkyl group having 1 to 10 carbon atoms include methyl groups, ethyl groups, propyl groups, isopropyl groups, butyl groups, isobutyl groups, s-butyl groups, t-butyl groups, pentyl groups, 1-methylbutyl groups, 2-methylbutyl groups, 3-methylbutyl groups, 1-ethylpropyl groups, 1,1-dimethylpropyl groups, 1,2-dimethylpropyl groups, 2,2-dimethylpropyl groups, cyclopentyl groups, hexyl groups, cyclohexyl groups, octyl groups, nonyl groups, and decyl groups.

In general formula (1), R² may be an alkenyl group having 2 to 10 carbon atoms, which is preferable from the standpoint of improving the hardness and the modulus of elasticity of the gas barrier film that is formed. R² is more preferably an alkenyl group having 2 to 6 carbon atoms and even more preferably an alkenyl group having 2 to 4 carbon atoms.

The alkenyl group having 2 to 10 carbon atoms and the alkynyl group having 2 to 10 carbon atoms may have a configuration that is straight, branched, or cyclic. Specific examples of the alkenyl group having 2 to 10 carbon atoms include vinyl groups, 1-propenyl groups, 2-propenyl groups, 3-butenyl groups, 5-hexenyl groups, and 7-octenyl groups. Specific examples of the alkynyl group having 2 to 10 carbon atoms include ethynyl groups, 1-propynyl groups, and 2-propynyl groups.

In general formula (1), R³ may be an alkoxy group having 1 to 10 carbon atoms, which is preferable because in this case, high gas barrier properties can be obtained. R³ is more preferably an alkoxy group having 1 to 6 carbon atoms and even more preferably an alkoxy group having 1 to 4 carbon atoms.

The alkoxy group having 1 to 10 carbon atoms may have a configuration that is straight, branched, or cyclic. Specific examples of the alkoxy group having 1 to 10 carbon atoms include methoxy groups, ethoxy groups, n-propoxy groups, i-propoxy groups, n-butoxy groups, i-butoxy groups, s-butoxy groups, t-butoxy groups, and n-pentoxy groups.

Preferably, the materials for a gas barrier film of the present embodiment includes an organosilane compound represented by any of general formulae (1A) to (1G), shown below.

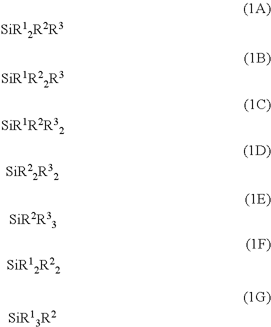

In the formulae, R¹ represents an alkyl group having 1 to 10 carbon atoms, preferably an alkyl group having 1 to 5 carbon atoms, more preferably an alkyl group having 2 to 4 carbon atoms, and even more preferably a branched alkyl group having 3 or 4 carbon atoms; R² represents an alkenyl group having 2 to 10 carbon atoms, preferably an alkenyl group having 2 to 4 carbon atoms, more preferably an alkenyl group having 2 or 3 carbon atoms, and even more preferably a vinyl group; and R³ represents an alkoxy group having 1 to 10 carbon atoms, preferably an alkoxy group having 1 to 4 carbon atoms, more preferably an alkoxy group having 1 to 3 carbon atoms, and even more preferably an alkoxy group having 1 or 2 carbon atoms. When R¹, R², or R³ is present in plurality, the plurality thereof may be identical to or different from one another.

Specific examples of organosilane compounds represented by general formula (1A) include methoxydimethylvinylsilane, ethoxydimethylvinylsilane, diethylmethoxyvinylsilane, ethylmethoxymethylvinylsilane, 2-propenylmethoxydimethylsilane, ethoxy-2-propenyldimethylsilane, diethyl-2-propenylmethoxysilane, and ethyl-2-propenylmethoxymethylsilane.

Specific examples of organosilane compounds represented by general formula (1B) include methoxymethyldivinylsilane, ethoxymethyldivinylsilane, ethylmethoxydivinylsilane, ethoxyethyldivinylsilane, di-2-propenylmethoxymethylsilane, ethoxydi-2-propenylmethylsilane, ethyldi-2-propenylmethoxysilane, and ethoxyethyldi-2-propenylsilane.

Specific examples of organosilane compounds represented by general formula (1C) include dimethoxymethylvinylsilane, ethyldimethoxyvinylsilane, dimethoxy-n-propylvinylsilane, isopropyldimethoxyvinylsilane, diethoxymethylvinylsilane, diethoxyethylvinylsilane, diethoxy-n-propylvinylsilane, diethoxyisopropylvinylsilane, 2-propenyldimethoxymethylsilane, 2-propenylethyldimethoxysilane, 2-propenyldimethoxy-n-propylsilane, 2-propenylisopropyldimethoxysilane, 2-propenyldiethoxymethylsilane, 2-propenyldiethoxyethylsilane, 2-propenyldiethoxy-n-propylsilane, 2-propenyldiethoxyisopropylsilane, and ethynyldimethoxymethylsilane.

Specific examples of organosilane compounds represented by general formula (1D) include dimethoxydivinylsilane, diethoxydivinylsilane, di-n-propoxydivinylsilane, diisopropoxydivinylsilane, di-n-butoxydivinylsilane, di-s-butoxydivinylsilane, diisobutoxydivinylsilane, di-t-butoxydivinylsilane, di-2-propenyldimethoxysilane, di-2-propenyldiethoxysilane, di-2-propenyldi-n-propoxysilane, di-2-propenyldiisopropoxysilane, di-2-propenyldi-n-butoxysilane, di-2-propenyldi-s-butoxysilane, di-2-propenyldiisobutoxysilane, di-2-propenyldi-t-butoxysilane, and diethynyldimethoxysilane.

Specific examples of organosilane compounds represented by general formula (1E) include trimethoxyvinylsilane, triethoxyvinylsilane, tri-n-propoxyvinylsilane, triisopropoxyvinylsilane, tri-n-butoxyvinylsilane, tri-s-butoxyvinylsilane, triisobutoxyvinylsilane, tri-t-butoxyvinylsilane, 2-propenyltrimethoxysilane, 2-propenyltriethoxysilane, 2-propenyltri-n-propoxysilane, 2-propenyltriisopropoxysilane, 2-propenyltri-n-butoxysilane, 2-propenyltri-s-butoxysilane, 2-propenyltriisobutoxysilane, 2-propenyltri-t-butoxysilane, and ethynyltrimethoxysilane.

Specific examples of organosilane compounds represented by general formula (1F) include dimethyldivinylsilane, diethyldivinylsilane, ethylmethyldivinylsilane, di-n-propyldivinylsilane, diisopropyldivinylsilane, methyl-n-propyldivinylsilane, ethyl-n-propyldivinylsilane, isopropylmethyldivinylsilane, ethylisopropyldivinylsilane, di-2-propenyldimethylsilane, and diethyldi-2-propenylsilane.

Specific examples of organosilane compounds represented by general formula (1G) include trimethylvinylsilane, triethylvinylsilane, ethyldimethylvinylsilane, diethylmethylvinylsilane, tri-n-propylvinylsilane, triisopropylvinylsilane, 2-propenyltrimethylsilane, and triethyl-2-propenylsilane.

Among these, organosilane compounds represented by formulae (1A) to (1C) are preferable from the standpoint of improving the hardness and the modulus of elasticity of the gas barrier film that is formed. Organosilane compounds represented by formula (1C) are more preferable.

The production of the organosilane compound represented by formula (1) can be carried out by using any of the methods reported in much Non-Patent Literature. Examples of methods for producing an organosilane compound (1) include an alkoxylation reaction of a vinylalkylhalosilane with an alcohol; an alkoxylation reaction of a vinylalkylhalosilane with a metal alkoxide; a reaction of a vinyltrialkoxysilane with an alkyl magnesium halide reagent or an alkyl lithium; and a reaction of an alkyltrialkoxysilane with a vinyl magnesium halide or a vinyl lithium. Thus, the production can be easily carried out by those skilled in the art.

### <Method for Producing Silicon Oxide Film>

According to an embodiment, a method for producing a silicon oxide film uses any of the above-mentioned organosilane compounds (materials for a gas barrier film) and an oxidizing agent. In the method, a silicon oxide film is produced by depositing a film on a substrate by using a PECVD process under conditions including a plasma power of 100 W or greater. The silicon oxide film that is produced may be a multi-layer film made up of multiple layers stacked on top of one another.

Since the production method of the present embodiment uses the above-mentioned material for a gas barrier film, the method enables the production of a silicon oxide film having high gas barrier properties and high flexural resistance that are exhibited even if the film thickness is reduced. Furthermore, the silicon oxide film produced by the production method of the present embodiment has a high visible light transmittance, a low haze value, high hardness, and a high modulus of elasticity.

In the instance where a silicon oxide film is produced by a PECVD process, it is essential that an oxidizing agent, in addition to an organosilane compound, be fed. Specifically, in the instance where a gas barrier film is produced by a PECVD process that uses an organosilane compound and an oxidizing agent as source materials, the organosilane compound is vaporized and fed to a deposition chamber in which a substrate has been mounted. Examples of methods for the vaporization include a method in which an organosilane compound is placed in a heated constant-temperature chamber, and pressure reduction is performed with a vacuum pump or the like to achieve vaporization; a method in which an organosilane compound is placed in a heated constant-temperature chamber, and a carrier gas, such as helium, neon, argon, krypton, xenon, or nitrogen, is injected to achieve vaporization; and a method (liquid injection method) in which an organosilane compound, as it is or in the form of a solution, is fed to a vaporizer and heated to achieve vaporization in the vaporizer.

Examples of the oxidizing agent include oxygen, ozone, oxynitrides, carbon dioxide, carbon monoxide, hydrogen peroxide, and water. The oxidizing agent may be a mixture of two or more oxidizing agents.

In the instance where a solution is formed, the solvent for use may be, for example, an ether, such as 1,2-dimethoxyethane, diglyme, triglyme, dioxane, tetrahydrofuran, or cyclopentylmethyl ether, or a hydrocarbon, such as hexane, cyclohexane, methylcyclohexane, ethylcyclohexane, heptane, octane, nonane, decane, benzene, toluene, ethylbenzene, or xylene. One of these may be used alone, or two or more of these that are mixed in any ratio may be used.

Thus, the organosilane compound and the oxidizing agent that have been fed to the deposition chamber react with each other in the plasma generated in the deposition chamber. Accordingly, a gas barrier film is formed on the substrate. While the deposition can be caused to proceed by the plasma alone, additional steps, such as irradiation with light, heating of the substrate, may be employed.

Any plasma generation source may be used, and examples thereof include capacitively coupled plasmas, inductively coupled plasmas, helicon wave plasmas, surface wave plasmas, and electron cyclotron resonance plasmas.

A deposition apparatus for use in the production of the silicon oxide film may be any chemical vapor deposition apparatus that is commonly used by those skilled in the art, and examples thereof include batch-type apparatuses, continuous-type apparatuses, and roll-to-roll apparatuses.

The deposition chamber may have a pressure of, for example, 0.1 to 100 Pa. It is preferable that the pressure be 1 to 75 Pa because in this case, the resulting gas barrier film has a lower WVTR, and controlling the degree of vacuum is easy. More preferably, the pressure is 5 to 50 Pa.

It is essential that a power (plasma power) of a high frequency power supply (RF power supply) be 100 W or greater. It is preferable that the plasma power be 300 to 2000 W because in this case, the resulting gas barrier film has a lower WVTR. The plasma power is more preferably 500 to 1750 W and even more preferably 700 to 1500 W.

A density of the power to be applied to the electrodes for plasma discharge is preferably 0.1 W/cm² or greater and more preferably 0.5 W/cm² or greater. It is even more preferable that the density be 2.0 W/cm² to 100 W/cm² because in this case, the resulting gas barrier film has a lower WVTR.

During the deposition, the substrate may have any temperature that is not greater than the upper temperature limit of the substrate. Preferably, the temperature is in a range of 0° C. to 300° C.

The substrate may be made of any material. The substrate may be a ceramic substrate made of a metal oxide, a metal nitride, a metal oxynitride, silicon oxide, or the like; a crystalline substrate made of silicon or the like; a metal-based substrate made of a metal, an alloy, or the like; a plastic substrate; a glass substrate; or the like. Among these, the plastic substrate may be made of, for example, a polyethylene terephthalate (PET), a polyethylene naphthalate (PEN), a polycarbonate (PC), a polyamide (PA), a polyimide (PI), a cycloolefin polymer (COP), a polyethylene (PE), a polypropylene (PP), a polystyrene (PS), a polyvinyl chloride (PVC), a polyvinyl alcohol (PVA), a triacetyl cellulose (TAC), a polyethersulfone (PES), a cycloolefin copolymer (COC), a polyacrylonitrile (PAN), an ethylene-vinyl alcohol copolymer (EVOH), an ABS resin, a methacrylic resin, an epoxy resin, a modified polyphenylene ether, a polyacetal, a polybutylene terephthalate, a polyacrylate, a polyarylate, a polysulfone, a polyamide-imide, a polyetherimide, a polyphenylene sulfide, a polyetheretherketone, a fluororesin, or the like.

A ratio (Y/X) of oxygen to the organosilane compound is preferably 1 or greater and more preferably 5 to 100, where X is a feed flow rate for the organosilane compound that is fed during the deposition, and Y is a feed flow rate for the oxygen that is fed during the deposition.

Preferably, the film thickness of the silicon oxide film that is produced by the production method of the present embodiment is 10 nm or greater so that high gas barrier performance can be realized. The film thickness is more preferably 50 nm to 1000 nm and even more preferably 100 nm to 1000 nm. In addition, from the standpoint of providing a thinner film, it is preferable that the film thickness be 500 nm or less. The film thickness is more preferably 50 to 500 nm and even more preferably 100 to 300 nm.

### <Silicon Oxide Film>

According to an embodiment, a silicon oxide film has a film thickness of 300 nm or less and a WVTR of 9.0×10⁻³ g/(m²·day) or less, where the WVTR is a rate obtained after a U-shape bending test is performed on the silicon oxide film under conditions including a bending radius of 5 mm and bending cycles of 100,000. The silicon oxide film can be produced, for example, by the above-described method for producing a silicon oxide film. In the present specification, the “silicon oxide film” is a film formed primarily of silicon dioxide (SiO₂). The WVTR, which is obtained after a bending test is performed, is preferably 1.0×10⁻⁶ to 9.0×10⁻³ g/(m²·day) and more preferably 1.0×10⁻⁶ to 5.0×10⁻³ g/(m²·day).

The silicon oxide film of the present embodiment has high gas barrier properties and high flexural resistance that are exhibited even if the film thickness is reduced.

In an instance where the silicon oxide film of the present embodiment is formed on a substrate to form a substrate equipped with a silicon oxide film, a difference (ΔT) is preferably 5% or less, and the difference (ΔT) is the result of subtracting a visible light transmittance of the substrate equipped with a silicon oxide film from a visible light transmittance of the substrate itself. The difference (ΔT) is more preferably 1% or less and even more preferably 0.2% or less. The ΔT indicates an amount of reduction in the visible light transmittance due to the deposition of the silicon oxide film. As referred to herein, the substrate may be any of the above-mentioned substrates as long as the substrate is light-transmissive. The substrate may be a plastic substrate or a glass substrate.

In an instance where the silicon oxide film of the present embodiment is formed on a substrate to form a substrate equipped with a silicon oxide film, a difference (ΔH) is preferably 5% or less, and the difference (ΔH) is the result of subtracting a haze value of the substrate itself from a haze value of the substrate equipped with a silicon oxide film. The difference (ΔH) is more preferably 1% or less and even more preferably 0.2% or less. The ΔH indicates an amount of increase in the haze value due to the deposition of the silicon oxide film. As referred to herein, the substrate may be any of the above-mentioned substrates as long as the substrate is light-transmissive. The substrate may be a plastic substrate or a glass substrate.

In the silicon oxide film, when the ΔT and ΔH are within the above-mentioned ranges, the absorption of light and scattering of light can be avoided. Accordingly, the silicon oxide film can be suitably used in an optical device, such as a light emitting element.

The modulus of elasticity of the silicon oxide film of the present embodiment is preferably 50 GPa or greater, preferably 55 GPa or greater, and more preferably 60 GPa or greater. The modulus of elasticity may have any upper limit and may be, for example, 100 GPa or less. The hardness of the silicon oxide film of the present embodiment is preferably 5.0 GPa or greater, preferably 6.0 GPa or greater, more preferably 7.0 GPa or greater, and even more preferably 8.0 GPa or greater. The hardness may have any upper limit and may be, for example, 20 GPa or less.

In the silicon oxide film, when the modulus of elasticity and the hardness of are within the above-mentioned ranges, a reduction in the gas barrier properties due to the formation of small scratches or voids, delamination from the substrate or another layer, and the like that are caused by an external impact or the like can be prevented.

Preferably, the film thickness of the silicon oxide film of the present embodiment is 10 nm or greater so that high gas barrier performance can be realized. The film thickness is more preferably 50 nm to 300 nm and particularly preferably 100 nm to 300 nm. In addition, from the standpoint of providing a thinner film, the film thickness of the silicon oxide film of the present embodiment is 300 nm or less. The film thickness is preferably 50 to 300 nm and more preferably 100 to 300 nm.

In the silicon oxide film of the present embodiment, the water vapor transmission rate (WVTR) obtained after a bending test is 9.0×10⁻³ g/(m²·day) or less, and, therefore, the water vapor transmission rate (WVTR) obtained before the bending test is also 9.0×10⁻³ g/(m²·day) or less, of course. In the silicon oxide film of the present embodiment, it is preferable, from the standpoint of providing high gas barrier performance, that the water vapor transmission rate (WVTR) be 1.0×10⁻⁶ to 9.0×10⁻³ g/(m²·day). The water vapor transmission rate is more preferably 1.0×10⁻⁶ to 9.0×10⁻⁴ g/(m²·day). Furthermore, in the silicon oxide film of the present embodiment, it is preferable that when the film thickness is 100 to 300 nm, the water vapor transmission rate (WVTR) be 9.0×10⁻⁴ g/(m²·day) or less because in this case, high gas barrier properties that are exhibited even if the film thickness is reduced are achieved.

Note that the water vapor transmission rate (WVTR) is measured by gas chromatography (a GC method).

Preferably, the silicon oxide film of the present embodiment has a carbon concentration in the film of 2.0 atom % or less as measured by X-ray photoelectron spectroscopy (XPS). The carbon concentration is more preferably 1.5 atom % or less and even more preferably 1.0 atom % or less.

In the silicon oxide film of the present embodiment, it is preferable that a ratio between a silicon (Si) concentration in the film and an oxygen (O) concentration in the film, as measured by X-ray photoelectron spectroscopy (XPS), be close to that of silicon oxide (SiO₂). Specifically, in terms of an elemental ratio, it is preferable that Si:O=1:1.7 to 2.3, it is more preferable that Si:O=1:1.8 to 2.2, and it is even more preferable that Si:O=1:1.9 to 2.1.

The silicon oxide film of the present embodiment may have a film density of 1.5 g/cm³ or greater, which is preferable from the standpoint of enhancing the gas barrier performance. The film density is more preferably 1.75 g/cm³ or greater and even more preferably 2 g/cm³ or greater. The film density may have any upper limit and may be, for example, 5 g/cm³ or less.

The silicon oxide film of the present embodiment may be a multi-layer film in which the silicon oxide film is layered on a substrate. Such a multi-layer film can be produced by the above-described method for producing a silicon oxide film.

### EXAMPLES

The present invention will now be described in more detail with reference to Examples. Note that the present invention is not limited to the Examples.

In Examples and Comparative Examples, silicon oxide films were deposited on substrates by using a common CVD apparatus that uses a capacitively coupled PECVD process to perform deposition. Specifically, the substrates used were a polyethylene naphthalate (PEN) film PQDA5 (manufactured by Teijin DuPont Films Japan Limited, a visible light transmittance of 88.3% and a haze value of 0.9%), which had a thickness of 125 μm, and a flat silicon wafer. A silicon oxide film was deposited on each of the substrates, and evaluations were performed on the resulting silicon oxide films. The source gases used were an organosilane compound that was vaporized in a constant-temperature chamber and an oxygen gas. The power supply used was a high-frequency power supply with a frequency of 13.56 MHz.

The film thickness of the deposited film was determined by capturing an image of a cross section of the film with a field emission scanning electron microscope JSM-7600F (FE-SEM manufactured by JEOL Ltd.) and then performing estimation. The film composition (including a carbon concentration) of the silicon oxide film was analyzed with an X-ray photoelectron spectrometer (XPS, manufactured by Ulvac-Phi Incorporated) PH15000 VersaProbe II. The films that were evaluated were those that used the silicon wafer as the substrate.

Regarding the silicon oxide films obtained in the Examples and the Comparative Examples, the water vapor transmission rate (WVTR), hardness, modulus of elasticity, flexural resistance, visible light transmittance, and haze value were measured with the methods described below. The results are shown in Table 1.

The water vapor transmission rate (WVTR), which served as an index of the gas barrier performance of the deposited film, was measured by gas chromatography (a GC method) with a water vapor transmission rate measuring device (GTR-3000 series, manufactured by GTR TEC Corporation) under the conditions of 40° C. and 90% RH. The films that were evaluated were those that used the PEN film as the substrate.

The flexural resistance of the deposited film was evaluated as follows. A bending test was performed with a device including a durability tester DLDM111LH and a U-shape folding test jig attached thereto (both are manufactured by Yuasa System Co., Ltd.), under conditions including a bending radius of 5 mm and bending cycles of 100,000, with the deposition surface of the sample being positioned on the inner side. Subsequently, the water vapor transmission rate (WVTR) of the sample was measured for the evaluation. The method for the measurement was a GC method, and the measurement was performed under the conditions of 40° C. and 90% RH. The films that were evaluated were those that used the PEN film as the substrate.

The visible light transmittance of the deposited film was measured with a spectrophotometer (U-4100, manufactured by Hitachi High-Tech Corporation) and determined as an average transmittance (of the film including the substrate) over wavelengths of 380 to 780 nm. Furthermore, the average transmittance of the substrate was measured in a similar manner. The films that were evaluated were those that used the PEN film as the substrate. Furthermore, the difference (ΔT), which is the result of subtracting the visible light transmittance of the film resulting from the deposition on the substrate from the visible light transmittance of the substrate itself, is shown in the table.

The haze value of the deposited film was measured with a method that is in accordance with JIS K 7136 by using a haze meter NDH5000 (manufactured by Nippon Denshoku Industries Co., Ltd.). The haze value of the substrate was measured in a similar manner. The films that were evaluated were those that used the PEN film as the substrate. The difference (ΔH), which is the result of subtracting the haze value of the substrate itself from the haze value of the film resulting from the deposition on the substrate, is shown in the table.

The modulus of elasticity and the hardness of the deposited film were determined as follows. A load displacement curve was obtained with an ultra-micro hardness tester (manufactured by KLA-Tencor, model number: Nano Indenter G200X Inforce 50) by using a nanoindentation method, and then calculation was performed based on the obtained load displacement curve. The nanoindentation method employed a continuous stiffness measurement method, which is a method that can acquire data in a depth direction so that the influence of the substrate can be reduced. The indenter that was attached to the ultra-micro hardness tester was a triangular pyramid indenter made of diamond. The films that were evaluated were those that used the silicon wafer as the substrate.

The carbon concentration, silicon concentration, and oxygen concentration of the deposited film were analyzed by X-ray photoelectron spectroscopy (XPS). The analyzer used was a PHI5000 Versa Probe II, manufactured by Ulvac-Phi Incorporated.

The film density of the deposited film was analyzed by X-ray reflectivity (XRR). For the measurement, the analyzer used was a SmartLab, manufactured by Rigaku Corporation, the X-ray source was CuKα radiation, the tube voltage was 45 kV, the tube current was 200 mA, and the optical system used was a two-crystal monochromator (Ge002). The analysis software used was GlobalFit ver. 2.0.6.0 (manufactured by Rigaku Corporation).

### Example 1

Silicon oxide films were deposited on a PEN film and a flat silicon wafer by using a PECVD process that used isopropyldimethoxyvinylsilane, as the organosilane compound, and oxygen, as the oxidizing agent. The deposition was carried out for 2 minutes at a feed flow rate of 7.0 sccm for the isopropyldimethoxyvinylsilane, a feed flow rate of 120 sccm for the oxygen, a deposition chamber pressure of 40 Pa, and a power of a high frequency power supply (RF power supply), which had a power supply frequency of 13.56 MHz, of 1000 W. The ratio (Y/X) of the feed flow rate for the oxygen to the feed flow rate for the isopropyldimethoxyvinylsilane was 17.1.

The film thickness of the resulting silicon oxide films was 200 nm. The deposition rate was 100 nm/min. The composition of the film contained 33 atom % Si and 67 atom % O and had a carbon concentration of less than 1.0 atom %. The film density was 2.19 g/cm³.

### Example 2

Silicon oxide films were deposited on a PEN film and a flat silicon wafer by using a PECVD process that used isopropyldimethoxyvinylsilane, as the organosilane compound, and oxygen, as the oxidizing agent. The deposition was carried out for 1.5 minutes at a feed flow rate of 7.0 sccm for the isopropyldimethoxyvinylsilane, a feed flow rate of 120 sccm for the oxygen, a deposition chamber pressure of 40 Pa, and a power of a high frequency power supply (RF power supply), which had a power supply frequency of 13.56 MHz, of 1000 W. The ratio (Y/X) of the feed flow rate for the oxygen to the feed flow rate for the isopropyldimethoxyvinylsilane was 17.1.

The film thickness of the resulting silicon oxide films was 150 nm. The deposition rate was 100 nm/min.

### Example 3

Silicon oxide films were deposited on a PEN film and a flat silicon wafer by using a PECVD process that used isopropyldimethoxyvinylsilane, as the organosilane compound, and oxygen, as the oxidizing agent. The deposition was carried out for 3 minutes at a feed flow rate of 7.0 sccm for the isopropyldimethoxyvinylsilane, a feed flow rate of 120 sccm for the oxygen, a deposition chamber pressure of 40 Pa, and a power of a high frequency power supply (RF power supply), which had a power supply frequency of 13.56 MHz, of 1000 W. The ratio (Y/X) of the feed flow rate for the oxygen to the feed flow rate for the isopropyldimethoxyvinylsilane was 17.1.

The film thickness of the resulting silicon oxide films was 300 nm. The deposition rate was 100 nm/min.

### Comparative Example 1

Silicon oxide films were deposited on a PEN film and a flat silicon wafer by using a PECVD process that used tetraethoxysilane, as the organosilane compound, and oxygen, as the oxidizing agent. The tetraethoxysilane used was a product from Tokyo Chemical Industry Co., Ltd. (GC purity >98%). The deposition was carried out for 2 minutes at a feed flow rate of 5.4 sccm for the tetraethoxysilane, a feed flow rate of 100 sccm for the oxygen, a deposition chamber pressure of 20 Pa, and a power of a high frequency power supply (RF power supply), which had a power supply frequency of 13.56 MHz, of 1000 W. The ratio (Y/X) of the feed flow rate for the oxygen to the feed flow rate for the tetraethoxysilane was 18.5.

The film thickness of the resulting silicon oxide films was 200 nm. The deposition rate was 100 nm/min. The prepared silicon oxide films were very brittle and easily cracked, and, therefore, the silicon oxide films could not be analyzed for the film properties.

### Comparative Example 2

Silicon oxide films were deposited on a PEN film and a flat silicon wafer by using a PECVD process that used tetraethoxysilane, as the organosilane compound, and oxygen, as the oxidizing agent. The tetraethoxysilane used was the same as that of Comparative Example 1. The deposition was carried out for 9 minutes at a feed flow rate of 5.4 sccm for the tetraethoxysilane, a feed flow rate of 160 sccm for the oxygen, a deposition chamber pressure of 30 Pa, and a power of a high frequency power supply (RF power supply), which had a power supply frequency of 13.56 MHz, of 1000 W. The ratio (Y/X) of the feed flow rate for the oxygen to the feed flow rate for the tetraethoxysilane was 29.6.

The film thickness of the resulting silicon oxide films was 770 nm. The deposition rate was 85 nm/min. The prepared silicon oxide films were brittle and cracked as a result of contact with another material or a film bending operation, and, consequently, the silicon oxide films could not be analyzed for some film properties.

TABLE 1

| | | Film | | WVTR After | | | | Modulus of |
|---|---|---|---|---|---|---|---|---|
| | | Thickness | WVTR | Bending Test | ΔT | ΔH | Hardness | Elasticity |
| — | Material | nm | g/(m² · day) | g/(m² · day) | % | % | GPa | GPa |
| Example 1 | Isopropyldimethoxyvinylsilane | 200 | 5.0E−04 | 1.6E−03 | 0.1 | 0.1 | 8.5 | 64.8 |
| Example 2 | | 150 | 9.0E−04 | 3.0E−03 | 0.1 | 0.1 | 8.2 | 62.5 |
| Example 3 | | 300 | 4.0E−04 | 1.5E−03 | 0.1 | 0.1 | 8.4 | 63.9 |

| Comparative | Tetraethoxysilane | 200 | Cracked upon contact | | | | |
|---|---|---|---|---|---|---|---|
| Example 1 | | | | | | | |
| Comparative | | 770 | 1.6E−03 | Cracked | 0.1 | 0 | Cracked |
| Example 2 | | | | | | | |

1. A silicon oxide film having a film thickness of 300 nm or less and a water vapor transmission rate (WVTR) of 9.0×10⁻³ g/(m²·day) or less, where the water vapor transmission rate is a rate obtained after a U-shape bending test is performed on the silicon oxide film under conditions including a bending radius of 5 mm and bending cycles of 100,000.

2. The silicon oxide film according to claim 1, wherein, in an instance where the silicon oxide film is formed on a substrate to form a substrate equipped with a silicon oxide film, a difference (ΔT) is 5% or less, the difference (ΔT) being a result of subtracting a visible light transmittance of the substrate equipped with a silicon oxide film from a visible light transmittance of the substrate itself, and a difference (ΔH) is 5% or less, the difference (ΔH) being a result of subtracting a haze value of the substrate itself from a haze value of the substrate equipped with a silicon oxide film.

3. The silicon oxide film according to claim 1, wherein the silicon oxide film has a modulus of elasticity of 50 GPa or greater and a hardness of 5.0 GPa or greater.

4. A material for a gas barrier film, the material comprising an organosilane compound represented by general formula (1), shown below: 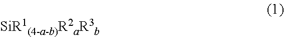
where R¹ represents a phenyl group, a benzyl group or an alkyl group having 1 to 10 carbon atoms, R² represents an alkenyl group having 2 to 10 carbon atoms or an alkynyl group having 2 to 10 carbon atoms, R³ represents an alkoxy group having 1 to 10 carbon atoms or a hydroxyl group, a is an integer of 1 to 4, and b is an integer of 0 to 3, provided that when R¹, R², or R³ is present in plurality, the plurality thereof may be identical to or different from one another.

5. The material for a gas barrier film according to claim 4, wherein R² is an alkenyl group having 2 to 4 carbon atoms.

6. The material for a gas barrier film according to claim 4, wherein R² is a vinyl group.

7. The material for a gas barrier film according to claim 4, wherein the organosilane compound is represented by any of general formulae (1A) to (1G), shown below: 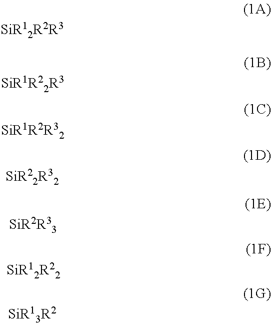
where R¹ represents an alkyl group having 1 to 10 carbon atoms, R² represents an alkenyl group having 2 to 10 carbon atoms, and R³ represents an alkoxy group having 1 to 10 carbon atoms, provided that when R¹, R², or R³ is present in plurality, the plurality thereof may be identical to or different from one another.

8. The material for a gas barrier film according to claim 4, wherein the organosilane compound is represented by any of general formulae (1A) to (1C), shown below: 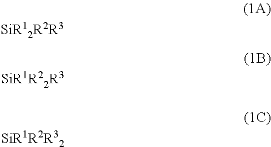
where R¹ represents an alkyl group having 1 to 5 carbon atoms, R² represents an alkenyl group having 2 to 4 carbon atoms, and R³ represents an alkoxy group having 1 to 4 carbon atoms, provided that when R¹, R², or R³ is present in plurality, the plurality thereof may be identical to or different from one another.

9. A method for producing a silicon oxide film comprising depositing the material for a gas barrier film according to claim 4 on a substrate by using a plasma-enhanced chemical vapor deposition process under conditions including a plasma power of 100 W or greater.

10. The silicon oxide film according to claim 2, wherein the silicon oxide film has a modulus of elasticity of 50 GPa or greater and a hardness of 5.0 GPa or greater.

11. A method for producing a silicon oxide film comprising depositing the material for a gas barrier film according to claim 5 on a substrate by using a plasma-enhanced chemical vapor deposition process under conditions including a plasma power of 100 W or greater.

12. A method for producing a silicon oxide film comprising depositing the material for a gas barrier film according to claim 6 on a substrate by using a plasma-enhanced chemical vapor deposition process under conditions including a plasma power of 100 W or greater.

13. A method for producing a silicon oxide film comprising depositing the material for a gas barrier film according to claim 7 on a substrate by using a plasma-enhanced chemical vapor deposition process under conditions including a plasma power of 100 W or greater.

14. A method for producing a silicon oxide film comprising depositing the material for a gas barrier film according to claim 8 on a substrate by using a plasma-enhanced chemical vapor deposition process under conditions including a plasma power of 100 W or greater.
